(19) United States
(12) Patent Application Publication
(10) Pub. No.: US 2009/0179657 A1
(43) Pub. Date: Jul. 16, 2009

(54) Printed circuit board for coupling probes to a tester, and apparatus and test system using same

(76) Inventors: Eddie Lee Williamson, Fort Collins, CO (US); Chris Richard Jacobsen, Fort Collins, CO (US); Myron Joseph Schneider, Fort Collins, CO (US); Dayton E. Norrgard, Fort Collins, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/008,590

(22) Filed: Jan. 11, 2008

(51) Int. Cl. G01R 31/02; G01R 1/02

(52) U.S. Cl. 324/754; 324/158.1

(57) ABSTRACT

In one embodiment, a printed circuit board (PCB) has a first side and a second side. The second side is opposite the first side. The PCB has a plurality of first contacts that provide an interface to a tester. The PCB also has a plurality of second contacts. The second contacts are provided on the second side of the PCB and provide an interface to probes of a probe layout. The PCB also has a plurality of electrical routes, with at least some of the electrical routes coupling multiple ones of the second contacts to single ones of the first contacts.

### BACKGROUND

Prior to shipping a circuit assembly (e.g., a printed circuit board or Multi-Chip Module), the circuit assembly is typically submitted to a battery of circuit tests. These tests are performed by a circuit “tester” and may include, for example, structural and/or functional tests. Structural tests may be used to determine, for example, the presence, correctness, orientation and “liveness” of the components of the circuit assembly. “Liveness” is a determination of whether a component accepts or responds to stimulus. Structural tests may also be used to determine whether the signal paths of a circuit assembly contain shorts or opens. In contrast to structural tests, functional tests may be used to determine whether components perform their intended functions. Typically, structural tests are performed while a circuit assembly is in an unpowered or minimally-powered state, while functional tests require a circuit assembly to be in a powered state.

Some testers are capable of performing many types of tests on many types of circuit assemblies. Given that the layouts of the different types of circuit assemblies can vary to a great degree, different circuit assemblies (or devices under test (DUTs) are coupled to a single circuit tester via a plurality of custom test fixtures. The custom test fixtures are often a source of great expense.

### BRIEF DESCRIPTION OF THE DRAWINGS

Illustrative embodiments of the invention are illustrated in the drawings, in which:

FIG. 1 illustrates an elevation of exemplary test system comprising exemplary apparatus for coupling a circuit assembly to a tester;

FIG. 2 illustrates a plan view of an exemplary probe layout for probes mounted in the probe plate shown in FIG. 1;

FIG. 3 illustrates a plan view of an exemplary layout of contacts on the printed circuit board shown in FIG. 1, as well as an exemplary registration of the probes shown in FIG. 2 to the contacts;

FIG. 4 illustrates a plan view of an exemplary layout of square-shaped pads on the printed circuit board shown in FIG. 1;

FIG. 5 illustrates a plan view of an exemplary layout of hexagonally-shaped pads on the printed circuit board shown in FIG. 1;

FIG. 6 illustrates a plan view of an exemplary layout of solder bead probes on the printed circuit board shown in FIG. 1;

FIG. 7 illustrates, in elevation, the use and positioning of an alignment plate between the probe plate and printed circuit board shown in FIG. 1;

FIG. 8 illustrates a plan view of the alignment plate shown in FIG. 7;

FIG. 9 illustrates a cross-section, in elevation, of an exemplary double-ended probe with spring-loaded tips;

FIG. 10 illustrates a cross-section, in elevation, of a modification to the double-ended probe shown in FIG. 9; and

FIG. 11 illustrates a modification of the probe plate shown in FIG. 1, to incorporate probes other than double-ended probes that contact both the circuit assembly and the printed circuit board.

Note that various elements of the drawings are not drawn to scale. This is because physical embodiments of some of the elements would be rather large in comparison to other physical embodiments of other elements, and if the elements were drawn to scale, it would be difficult to discern some of the smaller elements amongst the larger elements. The drawings are presented in a way that best illustrates the relationships and purposes of the elements depicted therein, and it is believed that one of ordinary skill in the art would readily understand how to vary the sizes of the elements to build physical embodiments of what is shown.

### DETAILED DESCRIPTION

As a preliminary manner, it is noted that, in the following description, like reference numbers appearing in different drawing figures refer to like elements/features. Often, therefore, like elements/features that appear in different drawing figures will not be described in detail with respect to each of the drawing figures.

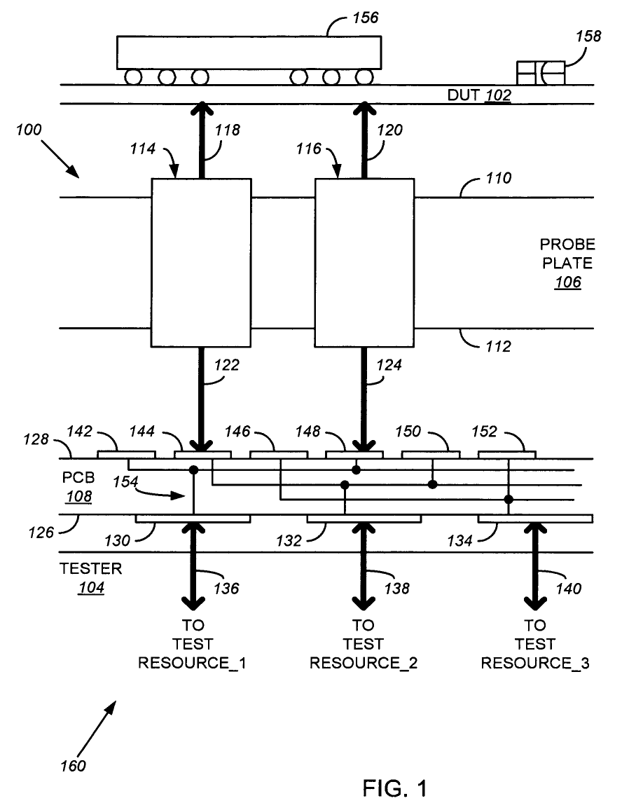

FIG. 1 illustrates an exemplary test system 160 comprising exemplary apparatus 100 for coupling a circuit assembly (i.e., a device under test (DUT 102)) to a tester 104. By way of example, the DUT 102 is shown to have a number of components 156, 158 mounted thereon. The apparatus 100 comprises a probe plate 106 and a printed circuit board (PCB 108). The probe plate 106 has a first side 110 and a second side 112; the second side 112 being opposite the first side 110. A plurality of double-ended probes 114, 116 is mounted in the probe plate 106. The double-ended probes 114, 116 have first ends 118, 120 projecting from the first side 110 of the probe plate 106, and second ends 122, 124 projecting from the second side 112 of the probe plate. The first ends 118, 120 provide an interface to the DUT 102, and may contact the DUT 102 as shown.

The PCB 108 also has a first side 126 and a second side 128; the second side 128 being opposite the first side 126. A plurality of first contacts 130, 132, 134 on the PCB 108 provides an interface to the tester 104 (e.g., an interface to test pins 136, 138, 140, and ultimately resources, of the tester 104). In one embodiment, the plurality of first contacts 130, 132, 134 is positioned on the first side 126 of the PCB 108. However, in alternate embodiments, the first contacts could be positioned elsewhere on the PCB 108, such as, on the edges of the PCB 108.

A plurality of second contacts 142, 144, 146, 148, 150, 152 is provided on the second side 128 of the PCB 108 and provides an interface to the second ends 122, 124 of the double-ended probes 114, 116. A plurality of electrical routes 154, on or within the PCB 108, couples the first and second contacts 130, 132, 134, 142, 144, 146, 148, 150, 152 of the PCB 108. At least some of the electrical routes 154 couple multiple ones of the second contacts 142, 144, 146, 148, 150, 152 to single ones of the first contacts 130, 132, 134.

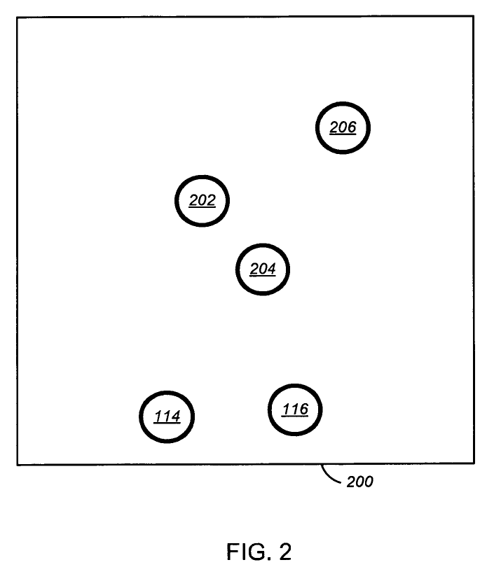

By necessity, the double-ended probes 114, 116 have a probe layout based on a layout of nodes to be probed on the DUT 102. A plan view of an exemplary probe layout 200 is shown in FIG. 2. In the past, such a probe layout 200 might have been coupled to a tester 104 via electrical routes in a custom wireless test fixture. Each route would have terminated in first and second pads for coupling a particular one of the probes 114, 116, 202, 204, 206 in the probe layout to a particular one of the test pins 136, 138, 140 provided by a tester 104. Although this solution eliminated some of the labor and expense of a wired test fixture, it still required custom wireless test fixtures, and different custom wireless test fixtures were needed to couple different probe layouts to a tester. As a result, the fixture expense for a user that wanted to test several different DUTs was significant.

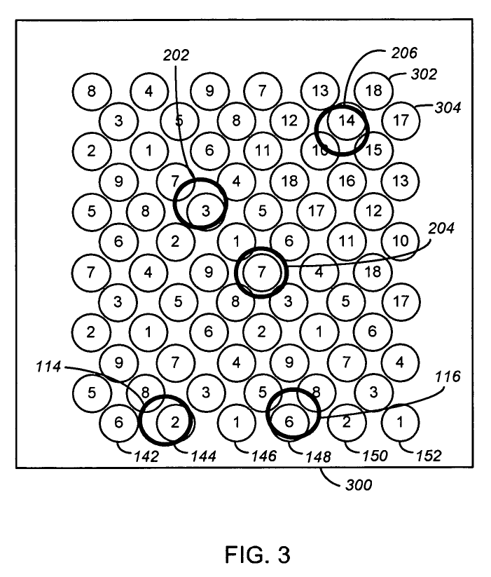

The PCB 108 shown in FIG. 1 differs from a custom wireless test fixture in that multiple ones of the PCB's second contacts 142, 144, 146, 148, 150, 152 (i.e., the contacts that provide an interface to the probes 114, 116) are coupled to ones of the PCB's first contacts 130, 132, 134 (i.e., the contacts that provide an interface to the tester 104). If each (or at least many) of the first contacts 130, 132, 134 are coupled to respective sets of the second contacts 142, 144, 146, 148, 150, 152, an exemplary plan view of the second contacts 142, 144, 146, 148, 150, 152, 302, 304 might appear as shown in FIG. 3, where each of the second contacts is labeled with a number that identifies the one of the first contacts 130 (label “2”), 132 (label “1”), 134 (label “6”) to which it is coupled. Preferably, the second contacts 142, 144, . . . 304 have a standardized layout 300 that is determined independently of the probe layout 200 that is designed for a particular DUT (such as DUT 102).

Also shown in FIG. 3 is an exemplary registration of the probes 114, 116, 202, 204, 206 shown in FIG. 2 to the “second contacts” 142, 144, . . . 304 shown in FIG. 3. Note that the multiple-to-one coupling of second contacts 142, 144, . . . 304 to first contacts 114, 116, 202, 204, 206 increases the probability that each test pin 136, 138, 140 of the tester 104 will be coupled to at least one of the probes 114, 116, 202, 204, 206. However, there is also a probability that a probe will not contact any of the second contacts 142, 144, . . . 304, as well as a probability that multiple probes will touch down on different ones of the second contacts (such as contacts 144 and 150) that are coupled to a common “first contact” 132 (see FIG. 1). To reduce these probabilities, the PCB 108 may be optimized in various ways.

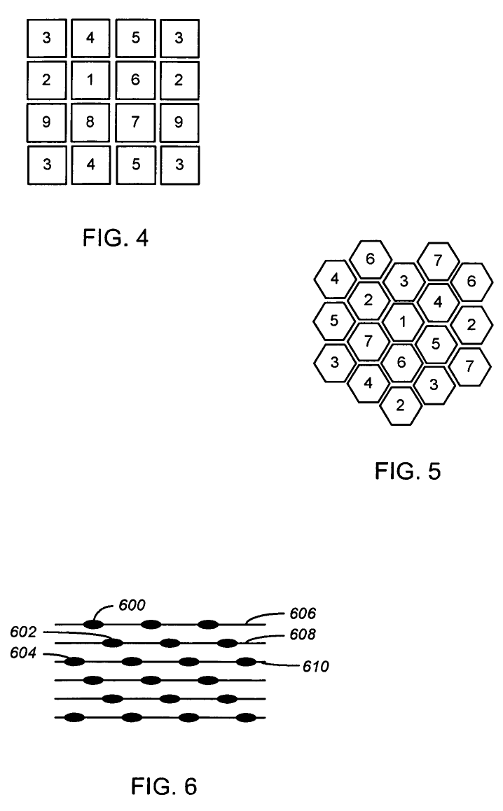

One way to optimize the PCB 108 is via an appropriate size, shape and placement of the second contacts 142, 144, . . . 304 (FIG. 3). Commonly, contact “pads” have circular shapes. However, arranging circular-shaped pads in columns and rows can lead to significant voids between the pads. It may therefore be desirable to stagger rows of circular-shaped pads, as shown in FIG. 3, so that the rows (and thus the pads) may be positioned more closely to one another. In this manner, the likelihood of a probe 114, 116, 202, 204, 206 contacting a void and missing one of the second contacts 142, 144, . . . 304 is minimized. Alternately, the second contacts 142, 144, . . . 304 may be provided as square-shaped or hexagonally-shaped pads, so that a uniform spacing may exist between the boundaries of all pads (see, FIGS. 4 and 5, respectively).

Another way to optimize the PCB 108 is to provide the second contacts 142, 144, . . . 304 (FIG. 3) in a number and a density that are greater, respectively, than a number and a density of probes 114, 116, 202, 204, 206 in the probe layout 200. For example, if it is expected that the spacing of nodes on a DUT 102, and thus the spacing of probes 114, 116, 202, 204, 206 in a probe layout 200, might be as small as 39 mils on-centers, then the second contacts 142, 144, . . . 304 might be formed with an on-center spacing of 20-25 mils. If the density of the second contacts 142, 144, . . . 304 exceeds the density of the probes 114, 116, 202, 204, 206, then it is unlikely that two probes will contact a single one of the second contacts 142, 144, . . . 304.

Yet another way to optimize the PCB 108 is to form the second contacts 114, 116, 202, 204, 206 as solder bead probes 600, 602, 604 instead of pads, as shown in FIG. 6. Solder bead probes 600, 602, 604 may be formed on surface traces 606, 608, 610 of the PCB 108, wherein the surface traces 600, 602, 604 form parts of the electrical routes 154 connecting the first and second contacts. Exemplary types of solder bead probes are described in detail in the following patents, which are hereby incorporated by reference for all that they disclose: U.S. Pat. No. 7,190,157 of Parker, and U.S. Pat. No. 7,259,576 of Parker et al. To provide a more random or pseudo-random distribution of solder bead probes, the traces on which solder bead probes are formed could change direction and/or drop to lower layers of the PCB 108, change order, and resurface on the PCB 108 in a new order.

Still another way to optimize the PCB 108 is to configure the electrical routes 154 of the PCB 108 such that multiple non-adjacent ones of the second contacts 142, 144, . . . 304 are coupled to single ones of the first contacts 130, 132, 134. This sort of optimization is reflected in the pattern of the numbered labels appearing on the second contacts 142, 144, . . . 304 shown in FIG. 3.

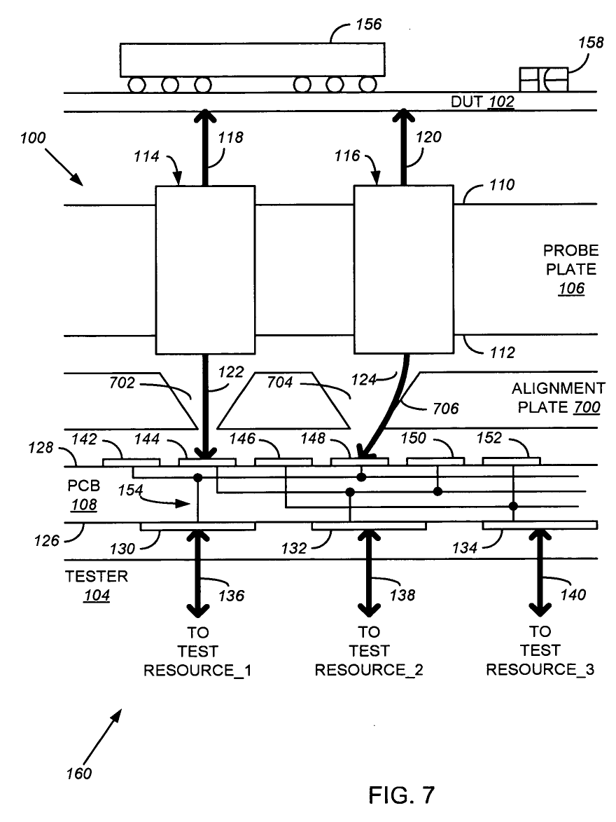

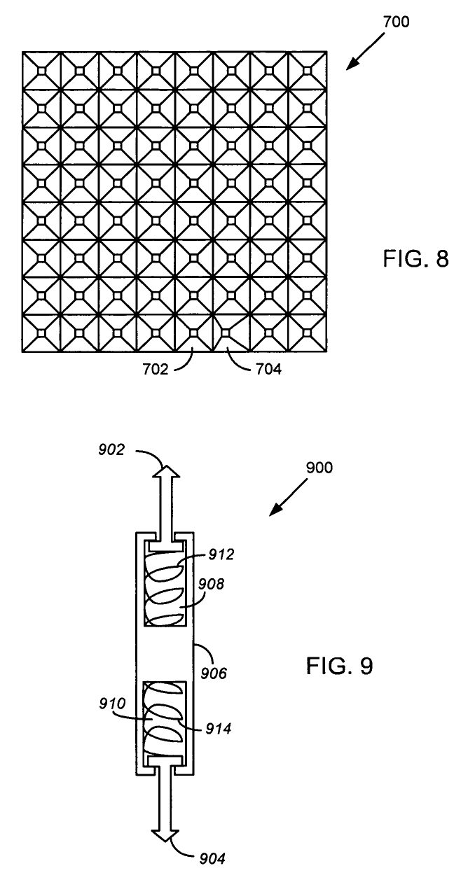

Even with the above optimizations, there still exists a probably that different probes will touch down on different “second contacts” 142, 144, . . . 304 that are coupled to a common one of the “first contacts” 130, 132, 134. FIGS. 7 and 8 therefore illustrate the use and positioning of an alignment plate 700, between the probe plate 106 and the PCB 108. The alignment plate 700 has a plurality of holes 702, 704 therein. The second ends 122, 124 of at least some (and preferably all) of the double-ended probes 114, 116 extend through ones of the holes 702, 704. At least one of the holes 702, 704 is associated with a tapered surface 706. Each tapered surface 706 is capable of causing the second end 124 of one of the double-ended probes 116 to bend and pass through a particular one of the holes (e.g., hole 704). In this manner, alignments between the probes 114, 116 and second contacts 142, 144, . . . 304 may be altered, and when two or more probes would otherwise touch down on ones of the second contacts 144, 150 that are coupled to a common first contact 130, one or more of the probes (e.g., probe 116) may be bent so that it touches down on a second contact 148 that is coupled to a unique one of the first contacts 130. In varying embodiments, the tapered surfaces may be provided be the walls of the holes 702, 704 themselves (as shown in FIG. 7), or by elements, such as funnels, that are attached to the mouths of the holes 702, 704. In some cases, the tapered surfaces may be provided by drilling or machining some or all of the holes to have a conical shape. The cross-section of each conical shape could be, for example, circular or square (although other shapes are possible).

FIG. 8 illustrates a plan view of the alignment plate 700, wherein a plurality of holes 702, 704 is drilled to form an array of holes. Note, however, that hole 704 is drilled off-center. Note that holes need not be drilled where probes are not present. Also note that the holes that are drilled need not (and likely will not) have uniform on-center spacings.

Although the alignment plate 700 is a custom part of the apparatus 100 (FIG. 7), it is noted that the alignment plate 700 may be constructed via simple drilling or machining steps, which steps are inexpensive to perform when compared to the cost of designing and manufacturing the stencils for constructing a custom PCB in place of standardized PCB 108.

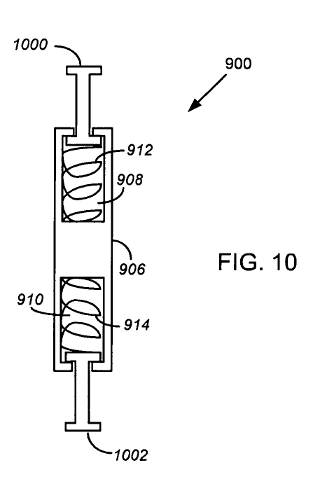

In some embodiments, the first or second ends 118, 120, 122, 124 of the double-ended probes 114, 116 may have fixed positions. However, to account for warping of the PCB 108 or DUT 102, and/or other device tolerances, both the first and second ends 118, 120, 122, 124 of the double-ended probes 114, 116 may comprise spring-loaded tips. An exemplary double-ended probe 900 with spring-loaded tips 902, 904 is shown in FIG. 9. The exemplary probe 900 comprises a central body portion 906 having two hollowed-out ends 908, 910. A spring 912, 914 and a probe tip 902, 904 is loaded into each of the hollowed-out ends 908, 910. The springs 912, 914 and probe tips 902, 904 may be retained in the hollowed-out ends 908, 910 via crimps or other securing mechanisms. As shown, the probe tips 902, 904 may have pointed ends. Alternately, the probe tips may have ends with other shapes. For example, if solder bead probes 600, 602, 604 are formed on traces 606, 608, 610 of the PCB 108 (FIG. 6) or DUT 102, one or both probe tips may have flat ends 1000, 1002 for contacting and crushing a respective solder bead probe (see FIG. 10).

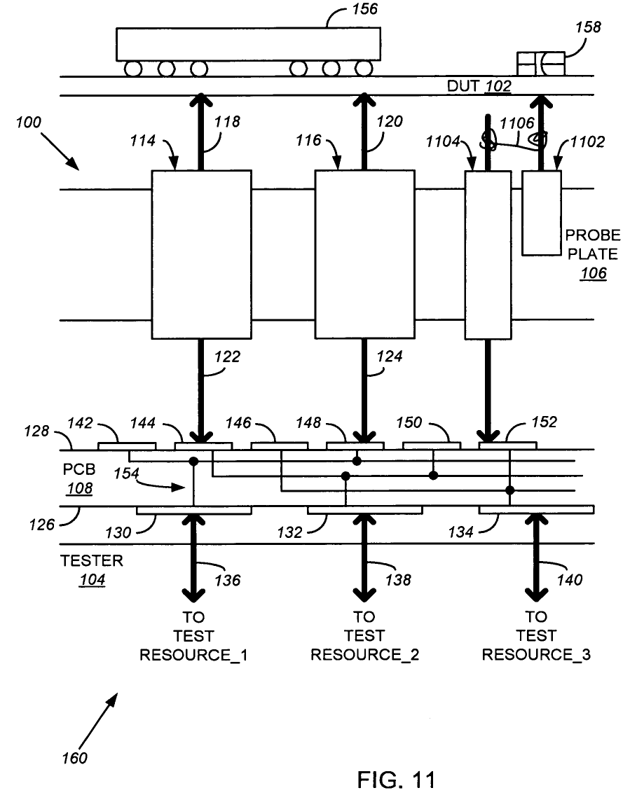

In addition to double-ended probes 114, 116 that contact both the PCB 108 and the DUT 102, other types of single- or double-ended probes may be mounted in the probe plate 106. For example, and as shown in FIG. 11, a first probe 1102 may be mounted in the probe plate 106 for contacting the DUT 102, but not the PCB 108, and a second probe 1104 may be mounted in the probe plate 106 for contacting one of the second contacts 152 of the PCB 108, but not the DUT. If one of the first or second probes 1102, 1104 extends through the probe plate 108, ends of the first and second probes 1102, 1104 may be electrically coupled via a wire 1106.

Although a goal of the PCB 108 and probe plate 106 is to eliminate the costs associated with a wired test fixture, it is recognized that engineering change orders (ECOs), issued after development of the probe plate 106 and optional alignment plate 700, may suggest the placement of probes that would create conflicts with already-established alignments between probes 114, 116, 1102, 1104 of the probe plate 106 and contacts 142, 144, . . . 304 of the PCB 108. The first and second probes 1102, 1104 shown in FIG. 11 provide an easy mechanism for handling ECOs. That is, the first probe 1102 may be mounted wherever it is needed, and the second probe 1104 may be mounted so as not to touch down on conflicting ones of the second contacts 142, 144, . . . 304 of the PCB 108. In some cases, ones of the second pads used to fulfill ECOs are located apart from other contacts on the PCB 108.

The probe plate 106, PCB 108 and optional alignment plate 700 may be provided to a user in various ways. In some embodiments, the PCB 108 may be provided as an independent article of manufacture. A user could then couple the PCB 108 to the tester 104 or to the probe plate 106. Alternately, a fixture manufacturer could incorporate the PCB 108 into a test fixture that includes the probe plate 106 and/or alignment plate 700. In other embodiments, the PCB 108 could be attached to the tester 104 apart from a test fixture, with the PCB 108 forming a permanent or semi-permanent part of the tester 104. Fixtures including the probe plate 106 and optional alignment plate 700 could then be mounted over the PCB 108 of the tester 104.

Depending on their configuration, the PCB 108, probe plate 106, and/or alignment plate 700 disclosed in FIGS. 1 and 7 (and elsewhere) may offer various advantages. For one, they can eliminate or drastically reduce the need to wire probes to one another. Second, PCB fabrication technology is well-understood and cost-effective, which can reduce the fixture costs for mating a DUT 102 to a tester 104. The drilling operations used to form the probe plate 106 and optional alignment plate 700 are also well-understood and cost-effective. Furthermore, the use of double-ended probes 114, 116, which apply forces through the probe plate 106 and the PCB 108 in a wholly vertical direction (i.e., without the offset of probes 1102, 1104 such as those used for ECO purposes (FIG. 11)) enables cheaper materials to be used for some tester or fixture components. For example, it may sometimes be possible to fit a tester 104 with lower-cost test pins 136, 138, 140. The standardized form of the PCB 108 can also enable modularization of the PCB 108. That is, the PCB 108 may be broken into modular pieces, and a user can be sold only the number of pieces that he needs to mate with the sizes of DUTs that he tests. It is also noted that the probe plate 106, PCB 108 and optional alignment plate 700 can often be manufactured faster than the components of currently offered test fixtures.

What is claimed is:

1. An article of manufacture for coupling probes of a probe layout to a tester, the article of manufacture comprising:
a printed circuit board (PCB) having i) a first side and a second side, the second side opposite the first side, ii) a plurality of first contacts on the PCB, the plurality of first contacts providing an interface to the tester, iii) a plurality of second contacts on the second side of the PCB, the plurality of second contacts providing an interface to the probes of the probe layout, and iv) a plurality of electrical routes, wherein at least some of the electrical routes couple multiple ones of the second contacts to single ones of the first contacts.

2. The article of manufacture of claim 1, wherein the plurality of second contacts are provided in a number and a density that are greater, respectively, than a number and a density of probes in the probe layout.

3. The article of manufacture of claim 1, wherein at least some of the electrical routes couple multiple non-adjacent ones of the second contacts to single ones of the first contacts.

4. The article of manufacture of claim 1, wherein the second contacts are hexagonally-shaped pads.

5. The article of manufacture of claim 1, wherein the second contacts are square-shaped pads.

6. The article of manufacture of claim 1, wherein the electrical routes comprise surface traces of the PCB, wherein the surface traces form parts of the electrical routes, and wherein the second contacts are solder bead probes formed on the surface traces.

7. Apparatus for coupling a device under test (DUT) to a tester, the apparatus comprising:
a probe plate having i) a first side and a second side, the second side opposite the first side, and ii) a plurality of double-ended probes mounted therein, the double-ended probes having first ends projecting from the first side of the probe plate and second ends projecting from the second side of the probe plate, the first ends providing an interface to the DUT; and
a printed circuit board (PCB) having i) a first side and a second side, the second side opposite the first side, ii) a plurality of first contacts on the PCB, the plurality of first contacts providing an interface to the tester, iii) a plurality of second contacts on the second side of the PCB, the plurality of second contacts providing an interface to the second ends of the double-ended probes, and iv) a plurality of electrical routes, wherein at least some of the electrical routes couple multiple ones of the second contacts to single ones of the first contacts.

8. The apparatus of claim 7, wherein the second contacts have a standardized layout, and wherein the double-ended probes have a probe layout based on a layout of nodes to be probed on the DUT and not the standardized layout of the second contacts.

9. The apparatus of claim 7, further comprising:
an alignment plate, positioned between the probe plate and the PCB and having a plurality of holes therein, wherein second ends of at least some of the double-ended probes extend through ones of the holes, and wherein at least one of the holes is associated with a tapered surface that causes the second end of one of the double-ended probes to bend and pass through a particular one of the holes.

10. The apparatus of claim 7, wherein the first ends of the double-ended probes comprise spring-loaded tips, and wherein the second ends of the double-ended probes comprise spring-loaded tips.

11. The apparatus of claim 7, wherein:
the probe plate has i) a first probe mounted therein for contacting the DUT, but not the PCB, and ii) a second probe mounted therein for contacting one of the second contacts of the PCB, but not the DUT; and
the apparatus further comprises a wire that electrically couples the first probe and the second probe.

12. The apparatus of claim 7, wherein the plurality of second contacts are provided in a number and a density that are greater, respectively, than a number and a density of probes in the probe layout.

13. The apparatus of claim 7, wherein at least some of the electrical routes couple multiple non-adjacent ones of the second contacts to single ones of the first contacts.

14. Apparatus for coupling probes of a probe layout to a tester, the apparatus comprising:
a printed circuit board (PCB) having i) a first side and a second side, the second side opposite the first side, ii) a plurality of first contacts on the PCB, the plurality of first contacts providing an interface to the tester, iii) a plurality of second contacts on the second side of the PCB, the plurality of second contacts providing an interface to the layout of probes, and iv) a plurality of electrical routes, wherein at least some of the electrical routes couple multiple ones of the second contacts to single ones of the first contacts; and
an alignment plate, positioned adjacent the second side of the PCB and having a plurality of holes therein, wherein at least one of the holes is associated with a tapered surface that causes an end of one of the probes in the probe layout to bend and pass through a particular one of the holes.

15. The apparatus of claim 14, wherein the plurality of second contacts are provided in a number and density that are greater, respectively, than a number and density of probes in the probe layout.

16. The apparatus of claim 14, wherein at least some of the electrical routes couple multiple non-adjacent ones of the second contacts to single ones of the first contacts.

17. A test system, comprising:
a tester for conducting electrical tests of devices under test; and
a printed circuit board (PCB) having i) a first side and a second side, the second side opposite the first side, ii) a plurality of first contacts on the PCB, the plurality of first contacts providing an interface to test resources of the tester, iii) a plurality of second contacts on the second side of the PCB, the plurality of second contacts providing an interface to a layout of probes for contacting a device under test, and iv) a plurality of electrical routes, wherein at least some of the electrical routes couple multiple ones of the second contacts to single ones of the first contacts.

18. The test system of claim 17, further comprising:
a test fixture comprising a probe plate, the probe plate having i) a first side and a second side, the second side opposite the first side, and ii) a plurality of double-ended probes mounted therein, the double-ended probes having first ends projecting from the first side of the probe plate and second ends projecting from the second side of the probe plate, the first ends providing an interface to a device under test, and the second ends providing an interface to ones of the second contacts of the PCB;
wherein the PCB is attached to the tester apart from the test fixture.

19. The test system of claim 18, wherein the test fixture further comprises an alignment plate, positioned adjacent the second side of the probe plate and having a plurality of holes therein, wherein second ends of at least some of the double-ended probes extend through ones of the holes, and wherein at least one of the holes is associated with a tapered surface that causes the second end of one of the double-ended probes to bend and pass through a particular one of the holes.

20. The test system of claim 17, further comprising:
a test fixture, the test fixture comprising a probe plate and the PCB, the probe plate having i) a first side and a second side, the second side opposite the first side, and ii) a plurality of double-ended probes mounted therein, the double-ended probes having first ends projecting from the first side of the probe plate and second ends projecting from the second side of the probe plate, the first ends providing an interface to a device under test, and the second ends providing an interface to ones of the second contacts of the PCB.
